(19) United States
(12) Patent Application Publication
(10) Pub. No.: US 2006/0280867 A1
(43) Pub. Date: Dec. 14, 2006

(54) Apparatus and method for depositing tungsten nitride

(76) Inventors: Jin-Ho Park, Seoul (KR); Seong-Hwee Cheong, Seoul (KR); Gil-Heyun Choi, Gyeonggi-do (KR); Sang-Woo Lee, Seoul (KR)

Correspondence Address: MARGER JOHNSON & MCCOLLOM, P.C., 210 SW MORRISON STREET, SUITE 400, PORTLAND, OR, 97204, US

(21) Appl. No.: 11/361,087

(22) Filed: Feb. 22, 2006

(30) Foreign Application Priority Data
Feb. 22, 2005 (KR) 2005-14651

(51) Int. Cl. C23C 16/00

(52) U.S. Cl. 427/248.1; 118/715

(57) ABSTRACT

An apparatus for depositing a thin film on a substrate includes a processing chamber, supply pipes, and discharge pipes. Each supply pipe is configured to supply a process gas to the processing chamber, and each discharge pipe is connected to one of the supply pipes and an inhale part configured to discharge gas remaining inside the one of the supply pipes. Each of the discharge pipes is separate from one another.

### CROSS REFERENCE TO RELATED APPLICATIONS

This application claims priority from Korean Patent Application 10-2005-0014651, which was filed on 22 Feb. 2005. Korean Patent Application 10-2005-0014651 is incorporated by reference in its entirety.

### BACKGROUND

1. Technical Field

This disclosure relates to an apparatus and a method for processing a substrate, and more particularly, to an apparatus and a method for forming a tungsten nitride layer on a substrate.

2. Description of the Related Art

Generally, various material layers can be deposited on a substrate in a manufacturing process of a semiconductor substrate. An apparatus for forming a tungsten nitride layer on a substrate includes a processing chamber and a plurality of supply pipes. The supply pipes introduce tungsten hexafluoride gas, ammonia gas, boron hydride gas, and silane gas to the inside of the processing chamber. A mass flow controller is installed to each supply pipe. A discharge pipe connected to a pump is connected to each supply pipe, and removes remaining gas in the supply pipe. The discharge pipe diverges from a position between a gas storage part and the mass flow controller. These discharge pipes are integrated into one pipe, and then connected to the pump.

Tungsten hexafluoride gas reacts easily with ammonia gas, boron hydride gas, and silane gas. Although gas is sequentially removed from each supply pipe, and the discharge pipe and the supply pipe are purged by purge gas, a portion of tungsten hexafluoride gas remaining in the integrated pipe reacts with ammonia gas, boron hydride gas, or silane gas, which is later removed from each supply pipe. Consequently, a reactant is deposited inside the pipe by the reaction, and particles are generated. After flowing into each discharge pipe and each supply pipe, the particles can constrict or block a passage by adhering to an inner wall of the mass flow controller in each supply pipe. Also, process gases flow into a pump through a discharge pipe, and pump malfunctions may occur due to the deposited gas in the pump.

Additionally, discharge lines are connected to each supply pipe to provide a sufficient amount of process gas to a processing chamber. Each of the discharge lines diverges from a position between the mass flow controller and the processing chamber and is connected to the pump controlling pressure in the processing chamber. Since tungsten hexafluoride gas, ammonia gas, boron hydride gas, and silane gas sequentially flow into the inside of the pump through the discharge lines, the process gases react with each other and a reactant may be deposited inside the pump. The reactant may cause pump malfunctions and increase the difficulty of maintaining a stable processing pressure in the chamber.

Embodiments of the invention address these and other disadvantages of the conventional art.

### SUMMARY

An apparatus according to some embodiments is capable of preventing a mass flow controller in a supply pipe from being blocked by particles when a tungsten nitride film is being deposited on a substrate. An apparatus according to some embodiments is capable of preventing a pump connected to a processing chamber from malfunctioning due to process gas through a discharge pipe when a tungsten nitride film is being deposited on a substrate.

A method according to some embodiments is capable of preventing a mass flow controller in a supply pipe from being blocked by particles when a tungsten nitride film is being deposited on a substrate. A method according to some embodiments is capable of preventing a pump connected to a processing chamber from malfunctioning due to process gas through a discharge pipe when a tungsten nitride film is being deposited on a substrate.

### BRIEF DESCRIPTION OF THE DRAWINGS

The accompanying drawings, which are included in and constitute a part of this application, illustrate exemplary embodiment of the invention and together with the written description serve to explain the principles of the invention.

FIG. 1 is a schematic diagram illustrating a deposition apparatus according to some embodiments of the invention.

FIG. 2 is a schematic diagram illustrating a deposition apparatus according to other embodiments of the invention.

FIG. 3 is a schematic diagram illustrating a deposition apparatus according to some other embodiments of the invention.

FIG. 4 is a schematic diagram illustrating a deposition apparatus according to still other embodiments of the invention.

FIGS. 5, 6, 7 and 8 are schematic diagrams illustrating the selective opening and closing of valves in the apparatus of FIG. 1 for various operational states.

### DETAILED DESCRIPTION

Preferred embodiments of the invention are described below, examples of which are illustrated in the accompanying drawings. However, the invention is not limited to the exemplary embodiments described hereafter; rather, the exemplary embodiments are described to provide an understanding of one or more inventive principles that may be found in all embodiments of the invention.

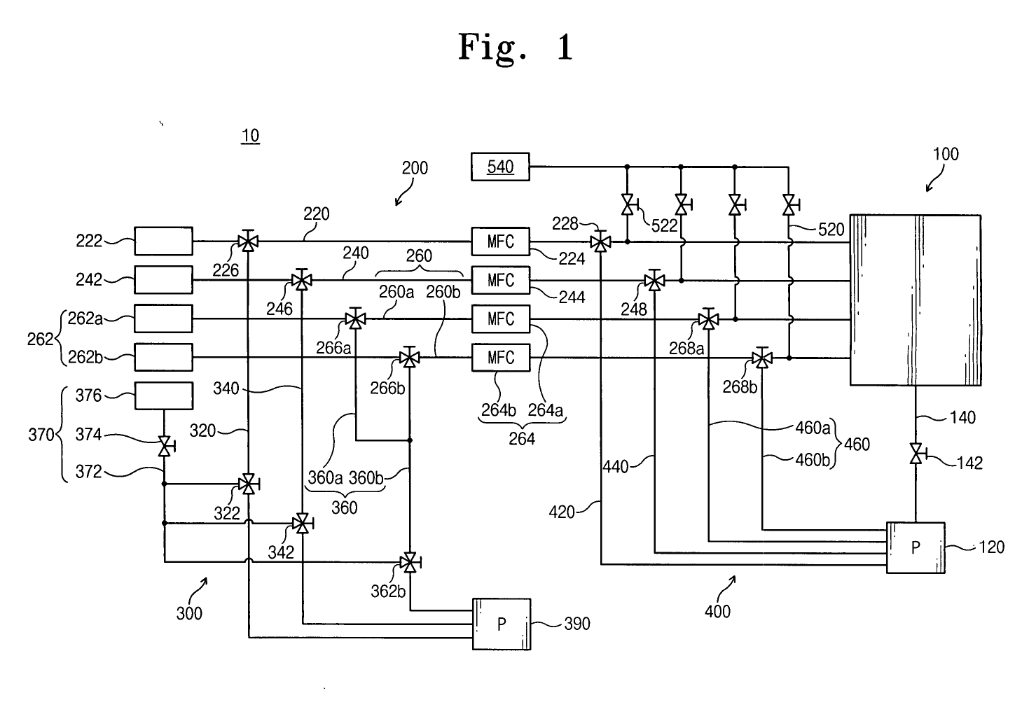

FIG. 1 is a schematic diagram illustrating a deposition apparatus according to some embodiments of the invention. Referring to FIG. 1, a deposition apparatus 10 includes a processing chamber 100, a gas supplying part 200, a discharge part 300, and a release part 400.

The processing chamber 100 can be sealed from the outside and provides a space for performing a film deposition process on a substrate. The process chamber 100 may have a structure for performing a deposition process for single wafer or multiple wafers. For example, a substrate support (not shown) for placing a wafer thereon may be disposed on a bottom in the processing chamber, and a shower head (not shown) for supplying process gas may be provided on a top in the processing chamber.

An exhaust pipe 140 is provided on a bottom wall or a side wall to maintain an inner pressure of the processing chamber 100 as a processing pressure and exhaust a reaction byproduct generated from the inside of the processing chamber 100. The exhaust pipe 140 includes an opening and closing valve, a flow control valve 142, and a pump 120 installed thereon.

The gas supply part 200 provides process gas inside the processing chamber 100. According to some embodiments, a tungsten nitride (WN) layer is deposited on a wafer by the deposition apparatus, and the gas supply part 200 provides tungsten hexafluoride (WF₆) gas, ammonia gas (NH₃), boron hydride (B₂H₆) gas, and silane gas (SiH₄) to an inside of the processing chamber 100. Alternatively, the gas supply part 200 may provide only one of these gases or a combination of several of these gases. Of course, the number and type of process gases may be different across different embodiments of the invention, but for the exemplary purposes of this disclosure the gas supply part 200 will be assumed to provide the four process gases specified above.

The gas supply part 200 includes a first supply pipe 220, a second supply pipe 240, and a third supply pipe 260. The first supply pipe 220 provides tungsten hexafluoride gas to the processing chamber 100 from a first storage part 222, the second supply pipe 240 provides ammonia gas to the processing chamber 100 from a second storage part 222, and the third supply pipe 260 provides boron hydride gas and silane gas to the processing chamber 100 from a third storage part 262. The third storage part 262 includes a 3-1 storage part 262A for storing boron hydride gas and a 3-2 storage part 262B for storing silane gas. The rotation 3-1 refers to a first portion of the third storage part while 3-2 refers to a second storage portion of the third storage part. The third supply pipe 260 includes a 3-1 supply pipe 260A for supplying boron hydride gas and a 3-2 supply pipe 260B for supplying silane gas. Additionally, tungsten hexafluoride gas and nitride gas may be mixed and stored in the first storage part 222.

Mass flow controllers (MFCs) 224, 244, 264 for controlling the flow of process gases are installed on each supply pipe 220, 240, 260, respectively. Alternatively, the flow of process gases could be controlled by a flow control valve. An opening and closing valve (not shown) for selectively opening and closing a passage of each supply pipes 220, 240, 260 can be installed between the storage parts 222, 242, 262 and the mass flow controllers 224, 244, 264, respectively.

A nitride gas supply pipe 520 and release pipes 420, 440, 460 are connected to each supply pipe 220, 240, 260, respectively. The nitride gas supply pipe 520, and the release pipes 420, 440, 460 are connected between the mass flow controllers 224, 244, 264 and the processing chamber 100.

Nitride gas flows into each supply pipe for supplying process gas through the nitride gas supply pipe 520, and delivers the process gas into the processing chamber 100. The opening and closing valve 522 and a flow control valve (not shown) are installed on each nitride gas supply pipe 520. The opening and closing valve 522 opens and closes an inner passage of the each nitride gas pipe. Additionally, nitride gas is provided through the nitride gas supply pipe 520 and is used to purge the inside of the processing chamber 100. Nitride gas for selectively delivering process gas and nitride gas for purging the inside of the processing chamber 100 can be provided through different supply pipes. Also, chemically stable inert gas may be used instead of nitride gas.

Initially, the rate at which process gas is supplied to the processing chamber 100 is variable, or non-uniform. Until the supply rate of the process gas is stable, the process gas supplied through the mass flow controllers 224, 244, 264 is released through a release part 400. The release part 400 includes release pipes 420, 440, 460 connected to each supply pipe 220, 240, 260, respectively. A pump 120 is connected to the release pipes 420, 440, 460. For simplification of the apparatus and costs saving, the pump 120 may be the same as a pump connected to the processing chamber 100. The release pipes 420, 440, 460 may be connected to supply pipes 220, 240, 260 by three-way valves 226, 246, 266, respectively. The three-way valves 226, 246, 266 allow the process gas supplied through the mass flow controller 224, 244, 264 to selectively flow either into the processing chamber 100 or into the release pipes 420, 440, 460.

The deposition of a tungsten nitride layer on a wafer may be accomplished through chemical vapor deposition (CVD), or atomic layer deposition (ALD). For example, when a deposition process is performed using ALD, gases may be sequentially introduced to the processing chamber 100 in the following specified order: boron hydride gas, purge gas, tungsten hexafluoride gas, purge gas, ammonia gas, purge gas, silane gas, purge gas, tungsten fluoride gas, purge gas, ammonia gas, and purge gas. Alternatively, the silane gas may be replaced by the boron hydride gas.

Periodically, the process gas remaining inside the supply pipes 220, 240, 260 should be removed. Since the process gas is sequentially supplied to the processing chamber 100, the process gas remaining inside the supply pipes 220, 240, 260 may be condensed and then deposited inside the supply pipes 220, 240, 260 or inside the mass flow controllers 224, 264, 284 during the time that the process gas is not supplied to the processing chamber 100. This deposition prevents a smooth flow of the process gas inside of the supply pipes 220, 240, 260 or the mass flow controllers 224, 244, 264. In particular, tungsten hexafluoride is easily condensed inside the supply pipes 220, 240, 260.

A discharge part 300 can remove any process gas remaining inside each supply pipe 220, 240, 260. The discharge part 300 includes a first discharge pipe 320 for removing gas remaining inside the first supply pipe 220, a second discharge pipe 340 for removing gas remaining inside the second supply pipe 240, and a third discharge pipe 360 for removing gas remaining inside the third supply pipe 260. The third discharge pipe 360 includes a 3-1 discharge pipe 360A for removing gas remaining inside a 3-1 supply pipe 260A and a 3-2 discharge pipe 360B for removing gas remaining inside a 3-2 supply pipe 260B.

Each discharge pipe 320, 340, 360 diverges from the supply pipes 220, 240, 260 through three-way valves 226, 246, 266 located between each storage part 222, 242, 262 and each mass flow controller 224, 244, 264. A position (that is, the installation position of the three-way valves 226, 246, 266) where the discharge pipes 320, 340, 360 diverge from the supply pipes 220, 240, 260 may be referred to as a junction. The three-way valves 226, 246, 266 allow the storage parts 222, 242, 262 and the mass flow controllers 224, 244, 264 to be connected to each other when process gas is supplied to the processing chamber 100. Also, the three-way valves 226, 246, 266 allow a region (hereinafter, referred to as a cleaning region) corresponding to a portion of the pipes 220, 240, 260 between the junction and the mass flow controllers 224, 244, 264 to be connected to discharge pipes 320, 340, 360 when the inside of the supply pipes 220, 240, 260 are cleaned. Each discharge pipe 320, 340, 360 is connected to an inhaler part. A pump 390 is used in the inhaler part, and the process gas remaining inside the cleaning region of the supply pipe 220, 240, 260 is forcibly inhaled by the pump. All discharge pipes 320, 340, 360 can be connected to the same pump 390 for a simple apparatus and cost reduction.

When all discharge pipes are connected to each other, the process gas that was forcibly inhaled from one discharge pipe can react with the remaining process gas that was forcibly inhaled from another discharge pipe. The reactant and the particles generated by the reaction can then flow into the cleaning region of a supply pipe through a discharge pipe again. Additionally, the reactant and the particles are deposited inside the supply pipe or the mass flow controller by flowing into the mass flow controller. Accordingly, the flow of the process gas can be blocked.

Thus, according to some embodiments of the invention, discharge pipes for discharging the process gases of a strong reaction are installed separately from each other. As described above, when tungsten hexafluoride gas, ammonia gas, boron hydride gas, and silane gas are used as process gas, the tungsten hexafluoride gas easily reacts with the other gases, but the ammonia gas, boron hydride gas, and silane gas don't react with each other quite so easily. Accordingly, a first discharge pipe 320 is connected with the first supply pipe 220 providing tungsten hexafluoride gas, and is installed separately from the second discharge pipe 340, the 3-1 discharge pipe 360A, and the 3-2 discharge pipe 360B. Additionally, the second discharge pipe 340, the 3-1 discharge pipe 360A, and the 3-2 discharge pipe 360B can be installed by various methods.

The second discharge pipe 340, the 3-1 discharge pipe 360A, and the 3-2 discharge pipe 360B may all be connected to each other or may all be separated from each other. Any two of the second discharge pipe 340, the 3-1 discharge pipe 360A, and the 3-2 discharge pipe 360B can be selectively connected to each other, and the remaining one can be separated from the others. However, referring to FIG. 1, since ammonia gas can react with boron hydride gas when the ammonia gas is heated, the second discharge pipe 340 that is connected to the second supply pipe 240 providing ammonia gas is preferably separated from the 3-1 discharge pipe 360A and the 3-2 discharge pipe 360B. Additionally, the 3-1 discharge pipe 360A and the 3-2 discharge pipe 360B can be connected to each other.

A purge gas supply part 370 is provided to purge the cleaning region of supply pipes 220, 240, 260 and the partial region of discharge pipes 320, 340, 360. The partial region includes the region between the three-way valve 226, 246, 266a, and 266b and the three-way valve 322, 342, and 362 in the discharge pipes 320, 340, and 360. The purge gas supply part 370 includes a purge gas supply pipe 372 connected to each discharge pipe 320, 340, 360. The purge gas is provided to the partial region of discharge pipes 320, 340, 360, and the cleaning region of supply pipes 220, 240, 260 from a purge gas storage part 376 through a purge gas supply pipe 372. Consequently, the inside of the region of discharge pipes 320, 340, 360 and the supply pipes 220, 240, 260 is purged. The purge gas supply pipe 372 is connected to the discharge pipes 320, 340, 360 by three-way valves 322, 342, 362B. An opening and closing valve 374 is installed at a purge gas supply pipe 372 to open and close an inner passage. The three-way valves 322, 342, 362B allow a pump 390 to be connected to supply pipes 220, 240, 260 when process gas remaining in the cleaning region of the supply pipes is inhaled. Also, the three-way valves 322, 342, 362B allow the purge gas supply pipe 372 to be connected to the supply pipes 220, 240, 260 when the inside of the cleaning region of the supply pipes is purged.

A removal of remaining gas in each supply pipe and a purge inside the supply pipe can be performed when process gas is not supplied to the processing chamber 100. When discharge pipes discharging the process gas of a strong reaction are separated from each other, or pumps connected to the discharge pipes are different to each other, the removal and the purge of the remaining gas may be performed simultaneously in a number of supply pipes.

Referring to FIG. 1, the supply pipes are separated and connected to a processing chamber 100. However, some or all of the supply pipes are connected to each other, and then can be connected to the processing chamber 100. But, the first supply pipe 220 providing tungsten hexafluoride gas needs to be separated from other supply pipes and then connected to the processing chamber 100.

According to some embodiments of the invention, since the first discharge pipe 320 that discharges tungsten fluoride gas from the first supply pipe 220 is installed separately from the other discharge pipes 340, 360, a passage discharging tungsten hexafluoride gas and a passage discharging other process gases are different to each other. Accordingly, the tungsten hexafluoride gas may be prevented from reacting with other process gases in the discharge pipes 320, 340, 360. Consequently, a reactant can not be deposited in the supply pipes 220, 240, 260 or mass flow controllers 222, 224, 264 to block the flow of process gas.

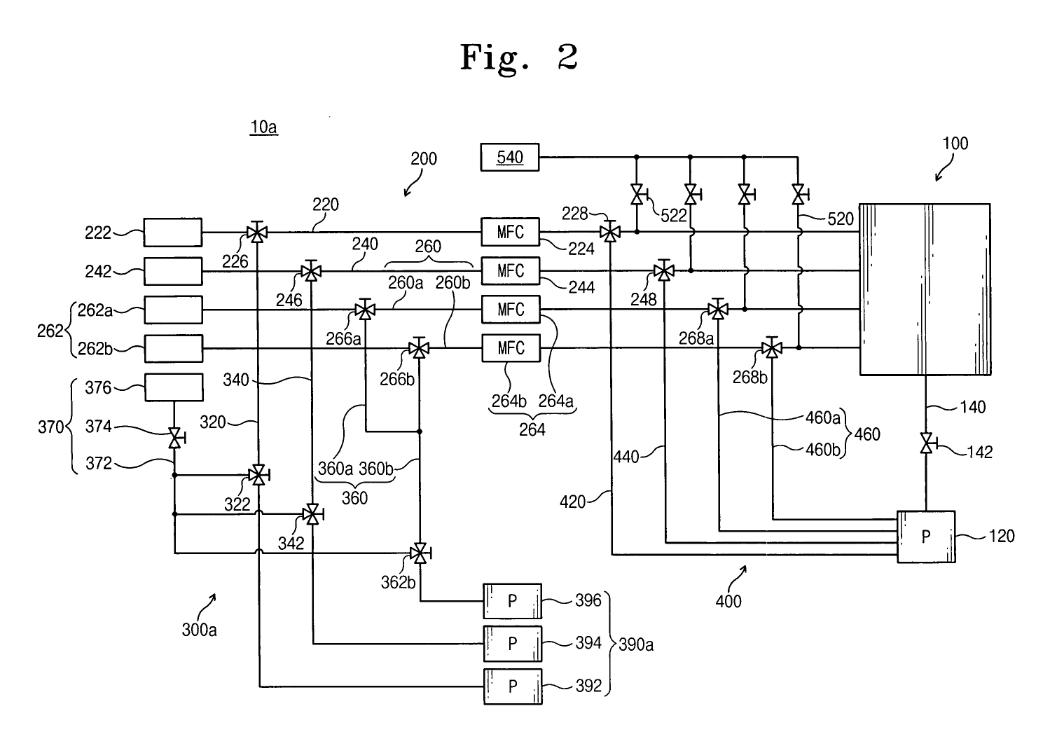

FIG. 2 is a schematic diagram illustrating a deposition apparatus 10A according to other embodiments of the invention. Like reference numerals in the drawings denote like elements. Thus, unnecessarily duplicative descriptions of elements that were described above with reference to FIG. 1 are omitted.

Referring to FIG. 1, the first discharge pipe 320, the second discharge pipe 340, the 3-1 discharge pipe 360A, and the 3-2 discharge pipe 360B are connected to the same pump 390 for a simple apparatus and cost reduction in the deposition apparatus 10. However, since all of the process gases (tungsten hexafluoride gas, ammonia gas, boron hydride gas, and silane gas) are inhaled into the same pump 390, the tungsten hexafluoride gas may react with other gases in the pump to deposit a reactant on the pump. This may cause the pump 390 to malfunction.

Referring to FIG. 2, in the discharge part 300A of the deposition apparatus 10A, each of the process gases discharged from the discharge pipes 320, 340, 360 are prevented from reacting with each other in a single pump. That is, the pump 392 that is connected to the first discharge pipe 320 for discharging tungsten hexafluoride is different from the pumps 394 and 396 that are connected to the other discharge pipes 340, 360.

In alternate embodiments, each of the 3-1 discharge pipe 360A and the 3-2 discharge pipe 360B may be directly connected to separate pumps, or, two of the second discharge pipe 340, the 3-1 discharge pipe 360A, and the 3-2 discharge pipe 360B may be connected to the same pump with the remaining one can connected to a different pump. Preferably, the pump 394 connected to the second discharge pipe 340 is different from the pump 396 connected to the 3-1 discharge pipe 360A to prevent ammonia gas from reacting with boron hydride gas due to increased temperature. Consequently, the illustrated embodiments can prevent the pumps 392, 394, 396 from malfunctioning.

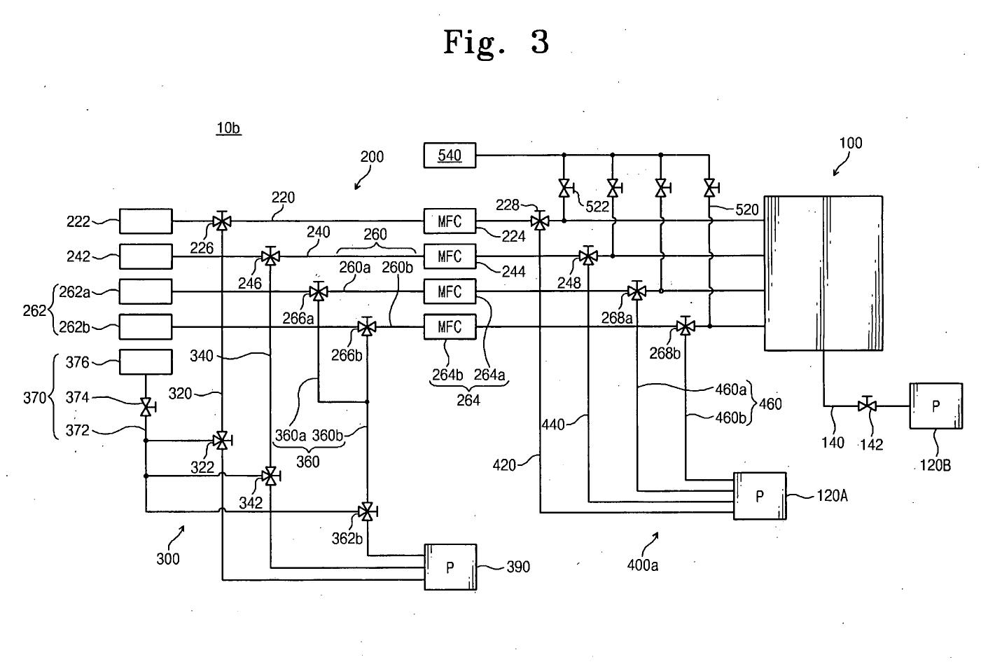

FIG. 3 is a schematic diagram illustrating a deposition apparatus 10B according to some other embodiments of the invention. Unnecessarily duplicative descriptions of elements that were described above with reference to FIGS. 1 and 2 are omitted.

Referring to FIG. 1, the pump 120 that is connected to release pipes 420, 440, 460 is the same pump that is connected to the processing chamber 100 for a simple apparatus and cost reduction in the deposition apparatus 10. However, tungsten hexafluoride gas, ammonia gas, boron hydride gas, and silane gas are sequentially inhaled into the pump 120 through each of release pipes 420, 440, 460. Since the tungsten hexafluoride gas may react with other gases, a reactant may be deposited on the pump 120 causing it to malfunction. Accordingly, if a malfunction of the pump 120 prevents the processing pressure from being stably maintained, a process defect may occur.

Referring to FIG. 3, a pump 120B that is connected to the release pipes 420, 440, 460 is different from the pump 120A that is connected to the processing chamber 100 in the release part 400A of the deposition apparatus 10B. In alternative embodiments, all of the release pipes 420, 440, 460 may be connected to a common pipe that is connected to the pump 120B, or the first release pipe 420 that releases tungsten hexafluoride gas from the first supply pipe 220 can be selectively connected to a different pump that is separated from the other release pipes 440 460. Consequently, the illustrated embodiments can prevent the pumps 120A and 120B from malfunctioning.

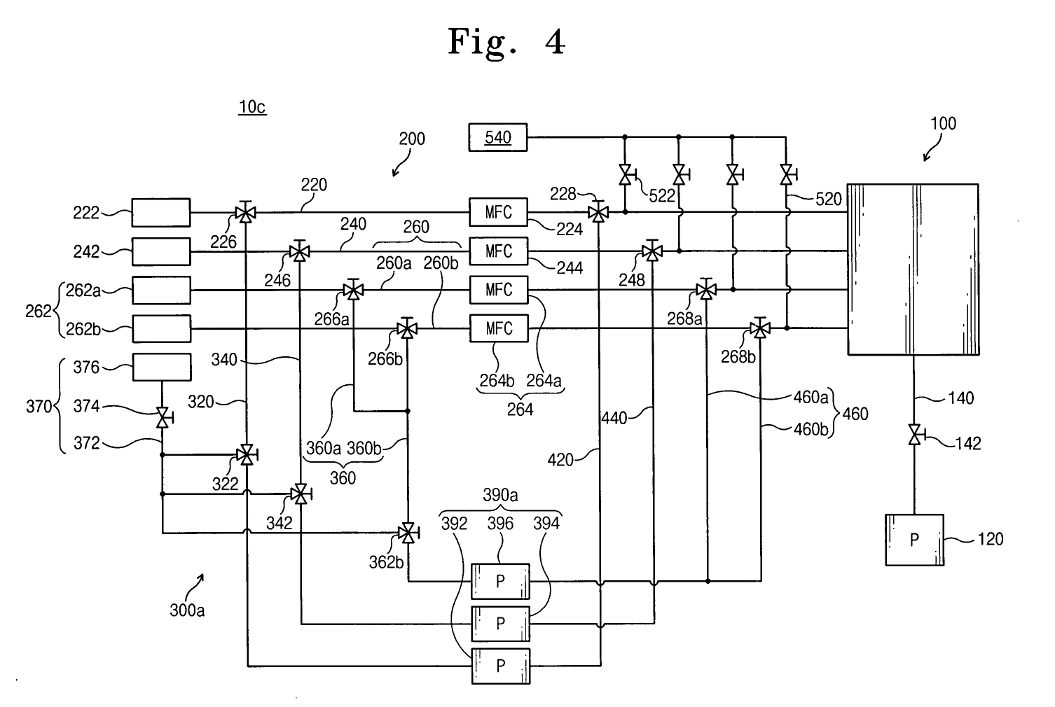

FIG. 4 is a schematic diagram illustrating a deposition apparatus 10C according to still other embodiments of the invention. Referring to FIG. 4, the discharge pipes 320, 340, 360 and their corresponding release pipes 420, 440, 460 are connected to a corresponding pump 392, 394, and 396, respectively. The release pipes 420, 440, 460 and an exhaust pipe 140 of the processing chamber 100 are all connected to different pumps. Additionally, the same process gas is inhaled into each pump 392, 394, 396 through the discharge pipes 320, 340, 360 and the release pipes 420, 440, 460 respectively. Consequently, deposition of the process gas can be prevented in the pumps 392, 394, 396 and the number of pumps can be reduced at the same time.

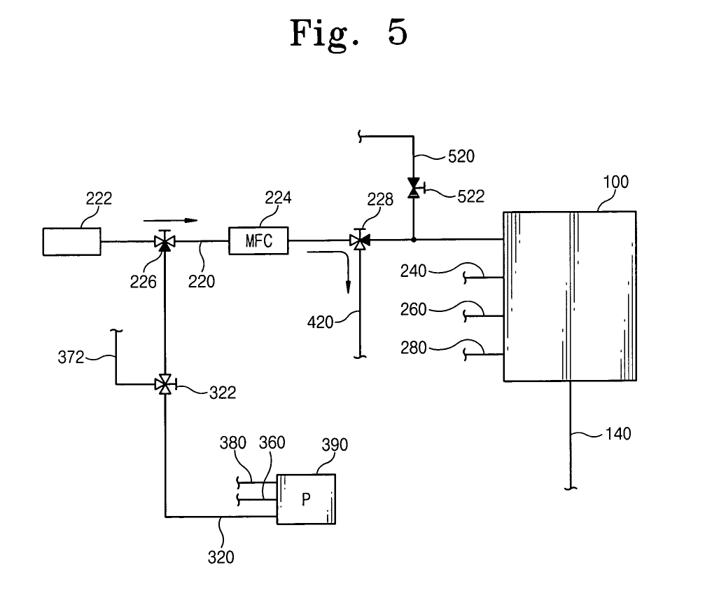

FIGS. 5, 6, 7 and 8 are schematic diagrams illustrating the selective opening and closing of valves in the apparatus of FIG. 1 for various operational states. In FIGS. 5, 6, 7 and 8, the white arrowheads represent an open state of the valves 226, 228, 322, 522, and the black arrowheads represent a closed state of the valves 226, 228, 322, 522. The direction of gas flow is indicated by arrows. For clarity, only the supply pipe 220, the discharge pipe 320, and the release pipe 420 are illustrated in FIGS. 5-8.

FIG. 5 is a schematic diagram illustrating a state of the valves 224, 226, 228, 322, 522 when tungsten hexafluoride gas is released through the release pipe 420 until an amount of supply of the tungsten hexafluoride gas is stable. Referring to FIG. 5, the three-way valve (hereinafter, referred to as a first three-way valve) 226 is installed between the mass flow controller 224 and the first storage part 222. The first three-way valve 226 is controlled to connect the first storage part 222 to the mass flow controller 224. Additionally, a three-way valve 228 (hereinafter, referred to as a second three-way valve) is installed between the mass flow controller 224 and the processing chamber 100. The second three-way valve 228 is controlled to connect the mass flow controller 224 to the release pipe 420. An opening and closing valve 522 mounted on the nitride gas supply pipe 520 is closed.

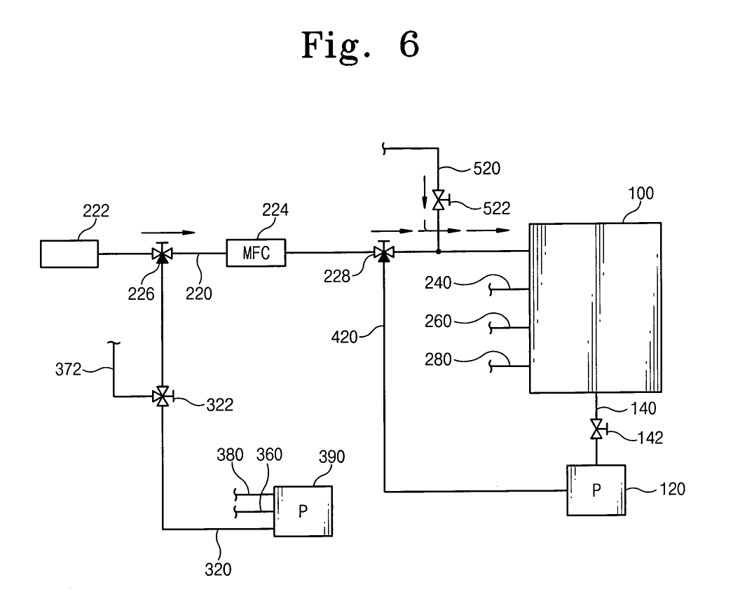

FIG. 6 is a schematic diagram illustrating a state of valves 224, 226, 228, 322, 522 when tungsten hexafluoride gas is supplied to a processing chamber 100. Referring to FIG. 6, the first three-way valve 226 is controlled to connect the first storage part 222 to the mass flow controller 224, and the second three-way valve 228 is controlled to connect the mass flow controller 224 to the processing chamber 100. Additionally, the opening and closing valve 522 is open in a nitride gas supply pipe 520.

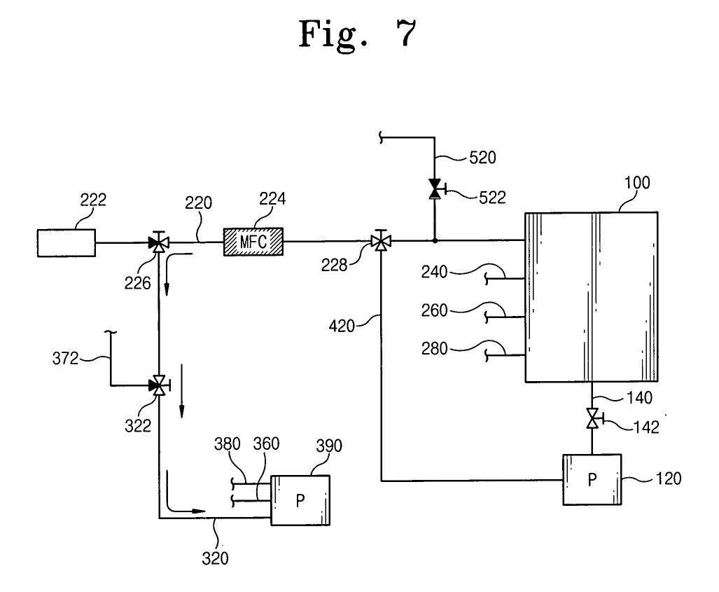

FIG. 7 is a schematic diagram illustrating a state of valves 224, 226, 228, 322, 522 when the tungsten hexafluoride gas remaining inside the cleaning region of the first supply pipe 220 is removed. Referring to FIG. 7, the mass flow controller 224 is closed, and the first three-way valve 226 is controlled to connect the cleaning region of the first supply pipe 220 to the first discharge pipe 320. A three-way valve 322 (hereinafter, referred to as a third three-way valve) installed at first discharge pipe 320 is controlled to connect the pump 390 to the cleaning region of the first supply pipe 220.

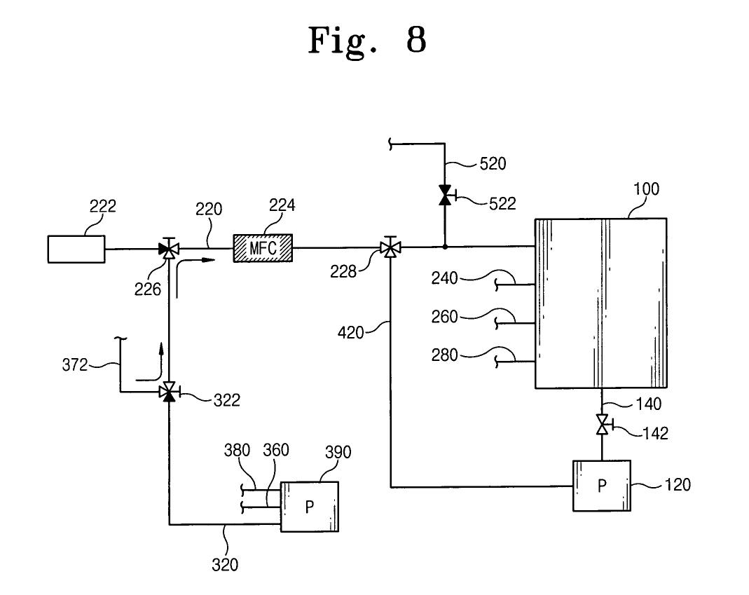

FIG. 8 is a schematic diagram illustrating a state of valves 224, 226, 228, 322, 522 when a cleaning region of a first supply pipe 220 and the inside of a first discharge pipe 320 are purged. Referring to FIG. 8, the mass flow controller 224 is closed, the first three-way valve 226 is controlled to connect the cleaning region of the first supply pipe 220 to the first discharge pipe 320, and the third three-way valve 322 is controlled to connect the cleaning region of the first supply pipe 220 to a purge gas supply pipe 372.

According to embodiments of the invention, when process gas remaining inside a supply pipe is removed and the inside of the supply pipe is purged, since the process gas of strong reaction is discharged by a separated discharge pipe or a different pump, the reaction of process gases with each other to form unwanted reactants in a supply pipe or a mass flow controller may be prevented.

Additionally, since the pump connected to a release pipe releasing process gas from a supply pipe is different from a pump connected to a processing chamber until the supply rate of supply gas is stable, the malfunction of the pump connected to the processing chamber, due to the process gases from a release pipe can be prevented.

The invention may be practiced in many ways. What follows are exemplary, non-limiting descriptions of some embodiments of the invention.

According to some embodiments of the invention, an apparatus for depositing tungsten nitride on a substrate includes a processing chamber, a gas supply part for supplying process gas to the processing chamber, and a discharge part for discharging gas remaining inside the gas supply part. The gas supply part includes a first supply pipe supplying tungsten hexafluoride gas to the processing chamber from a first storage part and having a first mass flow controller installed thereon, a second supply pipe supplying ammonia gas to the processing chamber from a second storage part and having a second mass flow controller installed thereon, and a third supply pipe supplying boron hydride gas or silane gas to the processing chamber from a third storage part and having a third mass flow controller installed thereon. The discharge part includes a first discharge pipe diverging from the first supply pipe and connected to an inhaler part, a second discharge pipe diverging from the second supply pipe and connected to the inhaler part, and a third discharge pipe diverging from the third supply pipe and connected to the inhaler part, where the first discharge pipe is separated from the second discharge pipe and the third discharge pipe.

According to some embodiments, the inhaler part may include a plurality of pumps and a pump connected to the first discharge pipe is different from a pump connected the second discharge pipe or the third discharge pipe.

According to other embodiments, the first discharge pipe may diverge from the first supply pipe between the first storage part and the first mass flow controller, and has a first valve allowing the first mass flow controller to be connected to a selected one of the first storage part and the first discharge pipe at a place where the first supply pipe diverges. The second discharge pipe diverges from the second supply pipe between the second storage part and the second mass flow controller, and has a second valve allowing the second mass flow controller to be connected to a selected one of the second storage part and the second discharge pipe at a place where the second supply pipe diverges. The third discharge pipe diverges from the third supply pipe between the third storage part and the third mass flow controller, and has a third valve allowing the third mass flow controller to be connected to a selected one of the third storage part and the third discharge pipe at a place where the third supply pipe diverges. The apparatus may further include a purge gas supply part for supplying purge gas, the purge gas supply part connected to the first discharge pipe, the second discharge pipe, and the third discharge pipe.

According to some embodiments, the apparatus may further include a first release pipe connected to the first supply pipe between the first mass flow controller and the processing chamber and having a pump installed thereon, the first release pipe configured to release tungsten fluoride gas supplied through the first supply pipe to an outside during a predetermined time at an initial state. The apparatus may further include a second release pipe connected to the second supply pipe between the second mass flow controller and the processing chamber and having a pump installed thereon, the second release pipe configured to release ammonia gas supplied through the second supply pipe to an outside during a predetermined time at an initial state. The apparatus may further include a third release pipe connected to the third supply pipe between the third mass flow controller and the processing chamber and having a pump installed thereon, the third release pipe configured to release boron hydride gas and silane gas supplied through the third supply pipe to an outside during a predetermined time at an initial state. The pumps connected to the first release pipe, the second release pipe, or the third release pipe are different from a pump connected to the processing chamber. The pumps connected to the release pipes may be the same as the pumps connected to the discharge pipe discharging the same process gas.

According to other embodiments of the invention, a method of depositing a tungsten nitride layer on a substrate includes supplying process gas including at least one of a boron hydride gas, silane gas, tungsten fluoride gas, and ammonia gas to a processing chamber through a plurality of supply pipes to form a tungsten nitride layer on a substrate, and removing gas remaining inside the supply pipe. The removing of the gas remaining inside a supply pipe supplying tungsten hexafluoride gas among the supply pipes is performed through a discharge pipe that diverges from a supply pipe that supplies the tungsten hexafluoride gas, and is separately arranged from a discharge pipe connected to supply pipe supplying ammonia gas and a discharge pipe connected to a supply pipe supplying boron hydride gas or silane gas. The method may further include supplying purge gas inside the supply pipes through the discharge pipe.

According to other embodiments, the removing of the gas remaining inside the supply pipe that supplies tungsten hexafluoride gas may be performed by a pump different from a pump to remove the boron hydride gas or the silane gas and a pump to remove the ammonia gas.

According to some embodiments, the method may further include releasing the process gas through a release pipe during a set time before supplying a processing gas to the processing chamber, and the releasing of the process gas may be performed by a pump that is different from a pump connected to the processing chamber. The releasing of the process gas may be performed by a pump that is connected to a discharge pipe that is discharging the same process gas that is being released by the release pipe.

According to some embodiments of the invention, an apparatus for depositing a thin film on a substrate may include a processing chamber, supply pipes for supplying process gas to the processing chamber, discharge pipes connected to each supply pipe, and an inhaler part to discharge gas remaining inside the supply pipe, wherein the discharge pipes may be separated from each other. The inhaler part may include pumps, and the discharge pipes may each be connected to a different pump.

According to other embodiments, a mass controller controlling a flow of the process gas may be installed on the each supply pipe, the discharge pipe may be diverged from the supply pipe between a process gas storage part and the mass flow controller, and a valve may be installed to selectively connect the mass flow controller to the process gas storage part or the discharge pipe. The apparatus may further include a purge gas supply pipe connected to the discharge pipe, wherein a valve may be further installed on the discharge pipe to selectively connect the supply pipe to the inhale part or the purge gas supply pipe.

According to other embodiments, the apparatus may further include release pipes connected to the each supply pipe to release process gas from the supply pipe until an amount of flow becomes stable by the mass flow controller, wherein a pump connected to the release pipes is different from a pump connected to the processing chamber. The release pipes may be connected to the pump connected to the discharge pipe discharging same process gas.

Exemplary devices and methods for depositing a tungsten nitride layer on a substrate were described above. However, it should be recognized that the inventive principles present in the described embodiments may be applied to any device or method that requires a gas supply part for supplying a plurality of strong reaction gases to a processing chamber.

It will be apparent to those skilled in the art that various modifications and variations can be made to the exemplary embodiments described above without departing from the inventive principles that are taught by those embodiments. Thus, it is intended that the invention cover all modifications and variations of the exemplary embodiments described above provided they fall within the scope of the attached claims and their equivalents.

1. An apparatus for depositing tungsten nitride on a substrate, the apparatus comprising:
a processing chamber;
a gas supply part configured to supply a process gas to the processing chamber, the gas supply part including a first supply pipe with a first mass flow controller installed thereon, the first supply pipe configured to supply a tungsten hexafluoride gas to the processing chamber from a first storage part, the gas supply part further including a second supply pipe with a second mass flow controller installed thereon, the second supply pipe configured to supply ammonia gas to the processing chamber from a second storage part, the gas supply part further including a third supply pipe having a third mass flow controller installed thereon, the third supply pipe configured to supply a boron hydride gas or a silane gas to the processing chamber from a third storage part; and
a discharge part configured to discharge the process gas remaining inside the gas supply part, the discharge part including a first discharge pipe that diverges from the first supply pipe and is connected to an inhaler part, a second discharge pipe that diverges from the second supply pipe and is connected to the inhaler part, and a third discharge pipe that diverges from the third supply pipe and is connected to the inhaler part, the first discharge pipe separated from the second discharge pipe and the third discharge pipe.

2. The apparatus of claim 1, the inhaler part comprising pumps, wherein a first pump that is connected to the first discharge pipe is different from a second pump that is connected to the second discharge pipe or the third discharge pipe.

3. The apparatus of claim 1, wherein the second discharge pipe is separated from the third discharge pipe.

4. The apparatus of claim 1, further comprising:
a first valve installed at a first junction between the first supply pipe and the first storage part where the first discharge pipe diverges from the first supply pipe, the first valve configured to selectively connect the first mass flow controller to one of the first storage part and the first discharge pipe;
a second valve installed at a second junction between the second supply pipe and the second storage part where the second discharge pipe diverges from the second supply pipe, the second valve configured to selectively connect the second mass flow controller to one of the second storage part and the second discharge pipe; and
a third valve installed at a third junction between the third supply pipe and the third storage part where the third discharge pipe diverges from the third supply pipe, the third valve configured to selectively connect the third mass flow controller to one of the third storage part and the third discharge pipe.

5. The apparatus of claim 4, further comprising a purge gas supply part connected to the first discharge pipe, the second discharge pipe, and the third discharge pipe.

6. The apparatus of claim 1, further comprising:
a first release pipe connected to the first supply pipe between the first mass flow controller and the processing chamber, the first release pipe having a first pump installed thereon and configured to release tungsten fluoride gas supplied through the first supply pipe to an outside during a first predetermined time;
a second release pipe connected to the second supply pipe between the second mass flow controller and the processing chamber, the second release pipe having a second pump installed thereon and configured to release ammonia gas supplied through the second supply pipe to the outside during a second predetermined time;
a third release pipe connected to the third supply pipe between the third mass flow controller and the processing chamber, the third release pipe having a pump installed thereon and configured to release boron hydride gas or silane gas supplied through the third supply pipe to the outside during a third predetermined time; and
a fourth pump that is connected to the processing chamber.

7. The apparatus of claim 6, the first pump connected to the first discharge pipe, the first discharge pipe configured to discharge tungsten fluoride gas, the second pump connected to the second discharge pipe, the second discharge pipe configured to discharge ammonia gas, the third pump connected to the third discharge pipe, the third discharge pipe configured to discharge boron hydride gas or silane gas.

8. A method of depositing a tungsten nitride layer on a substrate, the method comprising:
supplying gases to a processing chamber through supply pipes to form a tungsten nitride layer on a substrate, the gases including at least one chosen from the group consisting of a boron hydride gas and a silane gas, a tungsten hexafluoride gas, and an ammonia gas; and
removing the tungsten hexafluoride gas from a first supply pipe that supplies the tungsten hexafluoride gas to the processing chamber through a first discharge pipe that diverges from the first supply pipe, the first discharge pipe separate from a second discharge pipe that is configured to carry the ammonia gas and a third discharge pipe that is configured to carry the born hydride gas or the silane gas.

9. The method of claim 8, further comprising supplying a purge gas to the supply pipes through the discharge pipe.

10. The method of claim 8, wherein removing the tungsten hexafluoride gas from the first supply pipe comprises operating a first pump that is configured to pump the tungsten hexafluoride gas but is not configured to pump the ammonia gas, the boron hydride gas, or the silane gas.

11. The method of claim 8, further comprising, before supplying the gases to the processing chamber, releasing the gases through a release pipe using a first pump that is different than a second pump that is connected to the processing chamber.

12. The method of claim 11, the first pump connected to one of the first, second, and third discharge pipes, the release pipe configured to carry the same gas as the one of the first, second, and third discharge pipes.

13. An apparatus for depositing a thin film on a substrate, the apparatus comprising:
a processing chamber;
supply pipes, each supply pipe configured to supply a process gas to the processing chamber; and
discharge pipes, each discharge pipe connected to one of the supply pipes and an inhale part configured to discharge gas remaining inside the one of the supply pipes, each of the discharge pipes separate from one another.

14. The apparatus of claim 13, further comprising:
mass flow controllers, each mass flow controller installed on one of the supply pipes and configured to control a flow of the process gas in the one of the supply pipes; and
valves, each valve connecting one of the discharge pipes to one of the supply pipes, each valve installed on the one of the supply pipes between one of the mass flow controllers and a storage part configured to store the process gas at an end of the one of the supply pipes, each valve configured to selectively connect the one of the mass flow controllers to the storage part or the one of the discharge pipes.

15. The apparatus of claim 13, further comprising purge gas supply pipes, each purge gas supply pipe connected to one of the discharge pipes by another valve, the another valve configured to selectively connect the one of the discharge pipes to the inhale part or the corresponding purge gas supply pipe.

16. The apparatus of claim 13, the inhale part comprising pumps, each of the discharge pipes connected to a different one of the pumps.

17. The apparatus of claim 14, further comprising release pipes, each release pipe connected to one of the supply pipes, each release pipe configured to release the process gas from the one of the supply pipes until a flow of the process gas to the mass flow controller becomes stable, wherein a first pump connected to any one of the release pipes is different than a second pump connected to the processing chamber.

18. The apparatus of claim 17, the first pump connected to one of the discharge pipes, wherein the one of the discharge pipes and the any one of the release pipes is configured to carry the same process gas.
